(19) United States
(12) Patent Application Publication
(10) Pub. No.: US 2019/0311999 A1
(43) Pub. Date: Oct. 10, 2019

(54) SEMICONDUCTOR DEVICE AND WAFER-LEVEL PACKAGE EACH HAVING REDISTRIBUTION STRUCTURE, AND METHOD OF MANUFACTURING SEMICONDUCTOR DEVICE

(71) Applicant: HANA MICRON INC., Chungcheongnam-do (KR)

(72) Inventors: Hyung Jun KIM, Chungcheongnam-do (KR); Seung Tae LEE, Chungcheongnam-do (KR)

(73) Assignee: HANA MICRON INC., Chungcheongnam-do (KR)

(21) Appl. No.: 16/169,214

(22) Filed: Oct. 24, 2018

(30) Foreign Application Priority Data
Mar. 12, 2018 (KR) 10-2018/0028727

(51) Int. Cl. H01L 23/00

(52) U.S. Cl. CPC H01L 24/02; H01L 24/13; H01L 24/94; H01L 2224/13024; H01L 2924/3511; H01L 2224/02373; H01L 2224/0239; H01L 2924/01029; H01L 2224/02311; H01L 2224/0236

(57) ABSTRACT

A semiconductor device having a redistribution structure includes a redistribution layer provided on a semiconductor chip, and a passivation layer covering the redistribution layer while partially exposing the redistribution layer. The passivation layer has a thickness less than that of the redistribution layer.

### CROSS-REFERENCE WITH RELATED APPLICATIONS

This application claims priority to and the benefit of Korean Patent Application No. 10-2018-0028727, filed Mar. 12, 2018, the contents of which are incorporated into the present application by reference.

### BACKGROUND

### 1. Field of the Invention

The present disclosure relates to a semiconductor device and a wafer-level package each including a redistribution structure, and a method of manufacturing the semiconductor device, and more particularly, to a semiconductor device and a wafer-level package each having both a redistribution layer having a certain thickness or more and an anti-warpage unit, and a method of manufacturing the semiconductor device.

### 2. Discussion of Related Art

A semiconductor device includes various types of redistribution structures to apply semiconductor chips manufactured according to a certain standard to various semiconductor packages, semiconductor modules, electronic systems, etc.

FIG. 1 is a side view of part of a semiconductor device according to the related art.

As illustrated in FIG. 1, a semiconductor device including such a redistribution structure includes a semiconductor chip SC having thereon an integrated circuit, an electrode pad EP formed on the semiconductor chip SC, an insulating layer DL formed on the semiconductor chip SC and exposing the electrode pad EP, a first passivation layer PL formed on the insulating layer DL and exposing the electrode pad EP, a redistribution layer RDL electrically connected to the exposed electrode pad EP, a second passivation layer PL2 formed covering the redistribution layer RDL and exposing the redistribution layer RDL, an under bump metallurgy (UBM) layer UBM formed on the exposed redistribution layer RDL, and a solder bump SB formed on the UBM layer UBM. In this case, an alloy layer CM formed during a reflow process is provided between the UBM layer UBM and the solder bump SB. That is, the inclusion of the redistribution structure should be understood as including a structure electrically connecting the electrode pad EP and the solder bump SB, and particularly, the redistribution layer RDL.

Wafer-level packaging for packaging a semiconductor device including the redistribution structure has been introduced. The wafer-level packaging is performed while a semiconductor chip is not separated from a semiconductor wafer, and is advantageous in that a size of a semiconductor package can be reduced significantly.

FIG. 2 is a side view of part of a wafer-level package according to the related art.

As illustrated in FIG. 2, the wafer-level package has the same structure as the semiconductor device having the redistribution structure illustrated in FIG. 1, except that the semiconductor chip SC is replaced with a semiconductor wafer SW.

FIG. 3 illustrates an example in which a wafer-level package according to the related art warps.

In a semiconductor device and package including a redistribution structure, a redistribution layer RDL is generally formed to a thickness of less than 20 μm. In recent years, attempts have been made to improve the electrode efficiency of a semiconductor device or package by forming the redistribution layer RDL to be thicker than that of the related art. However, when the redistribution layer RDL is formed to be thicker than that of the related art, a degree to which the semiconductor wafer SW warps during a packaging process may exceed a threshold value as illustrated in FIG. 3, thereby reducing process yield.

### SUMMARY OF THE INVENTION

To address the above-described problem of the related art, the present disclosure is directed to a semiconductor device and a wafer-level package each including both a redistribution layer which is thicker than that of the related art and an anti-warpage unit, and a method of manufacturing the semiconductor device.

However, the present disclosure is not limited thereto and aspects of the present disclosure not mentioned herein will be clearly understood by those of ordinary skill in the art from the following description.

According to an aspect of the present disclosure, a semiconductor device having a redistribution structure includes (1) a semiconductor chip, (2) a redistribution layer provided on the semiconductor chip, and (3) a passivation layer covering the redistribution layer while partially exposing the redistribution layer. The passivation layer has a thickness less than that of the redistribution layer.

The redistribution layer may have a thickness greater than or equal to 20 μm and less than or equal to 30 μm.

A distance between an upper corner of the redistribution layer and an upper portion of the passivation layer spaced a minimum distance from the upper corner may be 5 μm or more.

A thickness of a side passivation layer which is a region of the passivation layer spaced a certain distance from a side of the redistribution layer may be greater than that of an upper passivation layer which is a region of the passivation layer located on the redistribution layer.

The thickness of the side passivation layer may be greater than or equal to 60% and less than 100% of that of the redistribution layer, and the thickness of the upper passivation layer may be greater than or equal to 40% and less than 75% of that of the redistribution layer.

As a ratio of a cross-sectional area ratio of the redistribution layer to that of the semiconductor chip is increased, the thickness of the passivation layer may be increased.

According to another aspect of the present disclosure, a semiconductor device having a redistribution structure includes (1) a semiconductor chip, (2) a redistribution layer provided on the semiconductor chip, and including copper and additives, and (3) a passivation layer covering the redistribution layer while partially exposing the redistribution layer. The additives include a brightener and a suppressor and exclude a leveler.

A content of the copper included in the redistribution layer may be 10 wt % or less.

A content of the suppressor included in the redistribution layer may be 2 wt % or more and 4 wt % or less.

According to another aspect of the present disclosure, a wafer-level package having a redistribution structure includes (1) a semiconductor wafer, (2) a redistribution layer provided on the semiconductor wafer, and (3) a passivation layer covering the redistribution layer while partially exposing the redistribution layer. The passivation layer has a thickness less than that of the redistribution layer.

According to another aspect of the present disclosure, a method of manufacturing a semiconductor device having a redistribution structure includes (a) forming a redistribution layer on a semiconductor wafer, and (b) forming a passivation layer to cover the redistribution layer while partially exposing the redistribution layer, the passivation layer having a thickness less than that of the redistribution layer.

### BRIEF DESCRIPTION OF THE DRAWINGS

The above and other objects, features and advantages of the present disclosure will become more apparent to those of ordinary skill in the art by describing in detail exemplary embodiments thereof with reference to the accompanying drawings, in which:

FIG. 1 is a side view of part of a semiconductor device according to the related art;

FIG. 2 is a side view of part of a wafer-level package according to the related art;

FIG. 3 illustrates an example in which a wafer-level package according to the related art warps;

FIG. 4 is a side view of part of a semiconductor device including a redistribution structure according to an embodiment of the present disclosure;

FIG. 5 is a side view of part of a wafer-level package including a redistribution structure according to an embodiment of the present disclosure;

FIG. 6 is an enlarged view of a region of FIG. 4 indicated by a broken line;

FIG. 7 illustrates examples of a region of a redistribution layer in a wafer-level package according to a thickness of the redistribution layer having a thickness of 10 μm (a) and 20 μm or more (b);

FIG. 8 is a graph showing a degree of a warpage occurred during a semiconductor device manufacturing process according to materials of a redistribution layer and a second passivation layer;

FIG. 9 illustrates composition ratios of (a) a material warped to a highest degree and (b) a material warped to a lowest degree among the materials of the redistribution layer of FIG. 8; and

FIG. 10 is a flowchart of a method of manufacturing a semiconductor device including a redistribution structure according to an embodiment of the present disclosure.

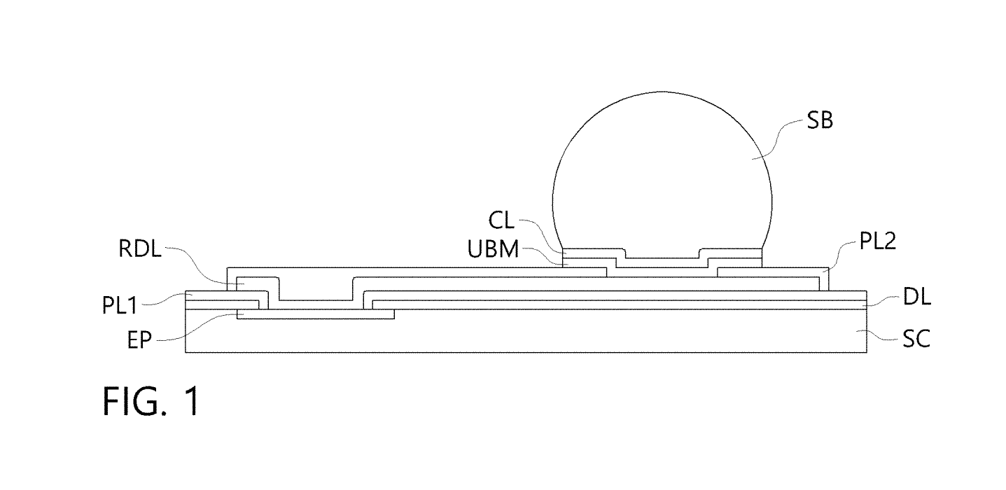

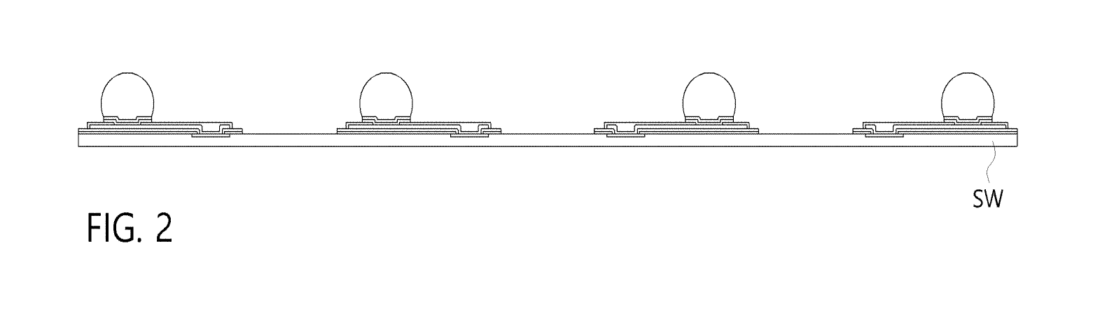

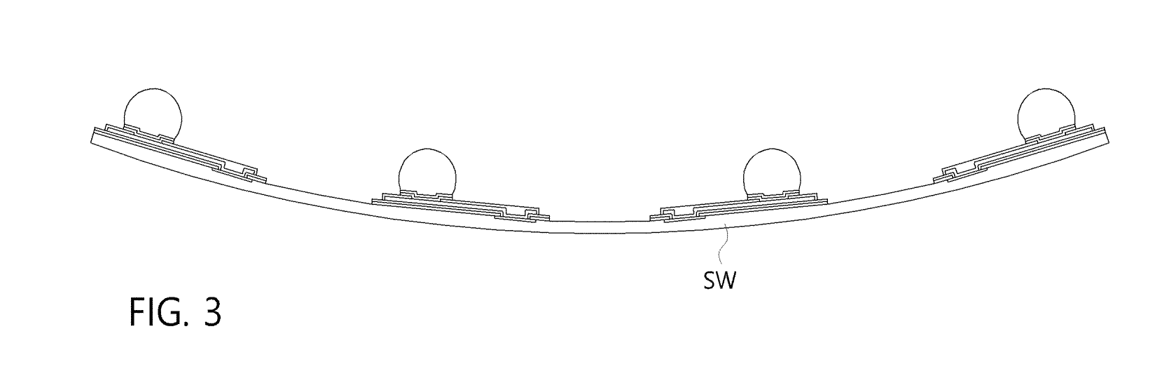

### DETAILED DESCRIPTION OF EXEMPLARY EMBODIMENTS

The foregoing purpose of the present disclosure, means for achieving the purpose, and effects of the present disclosure will become more apparent from the following description in conjunction with the accompanying drawings. Accordingly, the present disclosure will be easily implemented by those of ordinary skill in the technical field to which the present disclosure pertains. In the following description, well-known technologies related to the present disclosure are not described in detail if it is determined that they would obscure the present disclosure due to unnecessary detail.

The specific terms used herein are for the purpose of describing embodiments only and are not intended to limit the present disclosure. As used herein, singular forms may be understood to include plural forms in some cases, unless the context clearly indicates otherwise. As used herein, terms such as “comprise,” “include.” “provide,” “have” specify the presence of stated elements but do not preclude the presence or addition of one or more other elements.

As used herein, the terms “or,” “at least one (of)”, etc. include any and all combinations of one or more of the associated listed items. For example, “A or B” and “at least one of A and B” should be understood to include one or both of A and B.

Information, such as features, variables, or values, described herein with the expression “for example” may be less accurate, and thus, embodiments of the present disclosure should not be understood as being limited by effects such as modifications, including tolerances, measurement errors, limitations in measurement accuracy, and other commonly known factors.

It will be understood that when an element is referred to as being “coupled to” or “connected to” another element, the element can be directly coupled or connected to another element or another element may be interposed between the element and the other element. In contrast, it will be understood that when an element is referred to as being “directly coupled to” or “directly connected to” another element, another element is not interposed between the element and the other element.

Unless otherwise defined, all terms used herein have the same meaning as commonly understood by one of ordinary skill in the art to which the present disclosure pertains. It will be further understood that terms, such as those defined in commonly used dictionaries, will not be interpreted in an idealized or overly formal sense unless expressly so defined herein. Hereinafter, an embodiment of the present disclosure will be described in greater detail with reference to the accompanying drawings.

First, a semiconductor device including a redistribution structure according to an embodiment of the present disclosure will be described below.

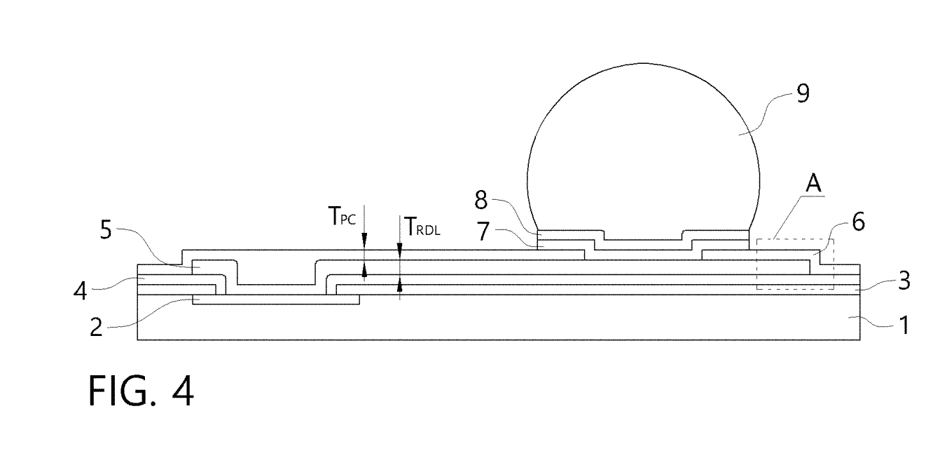

FIG. 4 is a side view of part of a semiconductor device including a redistribution structure according to an embodiment of the present disclosure.

As illustrated in FIG. 4, the semiconductor device including a redistribution structure according to an embodiment of the present disclosure includes a semiconductor chip 1, an electrode pad 2, an insulating layer 3, a first passivation layer 4, a redistribution layer 5, a second passivation layer 6, an under bump metallurgy (UBM) layer 7, an alloy layer 8, and a solder bump 9.

The semiconductor chip 1 includes an integrated circuit. For example, the semiconductor chip 1 may include, but is not limited to, various types of active or passive elements to form a semiconductor memory device (a DRAM, an SRAM, a flash memory, or the like), a processor element (a CPU, a DSP, or the like), an application-specific integrated circuit (ASIC) element, a micro-electro mechanical system (MEMS) element, a photoelectric element, a light-emitting element, an elastic wave filter element, etc.

Although FIG. 4 illustrates one semiconductor chip 1, the number of the semiconductor chip 1 is not limited thereto and a plurality of semiconductor chips 1 may be provided or stacked.

The electrode pad 2 is formed on the semiconductor chip 1, via which an input signal is input to or an output signal is output from the semiconductor chip 1. That is, the electrode pad 2 may be electrically connected to the integrated circuit of the semiconductor chip 1, thereby expanding a function of the semiconductor chip 1 to the outside. For example, the electrode pad 2 may be formed of a metal having a low specific resistance such as aluminum (Al), copper (Cu), or the like. Although FIG. 4 illustrates one electrode pad 2, the number of the electrode pad 2 is not limited to one and a plurality of electrode pads 2 may be provided.

The insulating layer 3 is formed on the semiconductor chip 1, and exposes part of an upper surface of the electrode pad 2. For example, the insulating layer 3 may be formed of an inorganic insulating material such as silicon nitride but is not limited thereto.

The first passivation layer 4 is formed on the insulating layer 3, and exposes part of the upper surface of the electrode pad 2. In this case, the first passivation layer 4 may be selectively formed.

The redistribution layer is electrically connected to the electrode pad 2 exposed via the insulating layer 3 and the first passivation layer 4, and is formed on the insulating layer 3 and the first passivation layer 4. In particular, the redistribution layer 5 is formed to a thickness greater than a thickness (20 μm or less) of a redistribution layer in the related art so as to improve the electrode efficiency (for example, to reduce a resistance) of the semiconductor device or package.

That is, the thickness of the redistribution layer 5 is preferably in a range of 20 μm to 30 μm. In this case, the thickness of the redistribution layer 5 is limited to 20 μm or more to form the redistribution layer 5 to be thicker than that of the related art, and is limited to 30 μm or less to operate an anti-warpage unit. That is, if the thickness of the redistribution layer 5 is greater than 30 μm, the redistribution layer 5 is extremely thick and thus is likely to warp to a degree greater than a threshold level even when an anti-warpage unit to be described later is provided.

The second passivation layer 6 is formed to cover the redistribution layer 5, and exposes part of an upper surface of the redistribution layer 5.

The first passivation layer 4 and the second passivation layer 6 prevent an unnecessary electrical short-circuit between the electrode pad 2, the redistribution layer 5 and the UBM layer 7, and prevent external physical/chemical damage to these components. For example, the first passivation layer 4 and the second passivation layer 6 may be formed of a polymer material. That is, the first passivation layer 4 and the second passivation layer 6 may include, but are not limited to, a general-purpose polymer such as polymethylmethacrylate (PMMA), polystyrene (PS), or polybenzoxazole (PBO), an acrylic-based polymer, an imide-based polymer, an arylether-based polymer, an amide-based polymer, a fluorinate polymer, a p-xylene-based polymer, a vinylalcohol-based polymer, a polymer derivative having a phenol group, or the like.

The UBM layer 7 is formed on the redistribution layer 5 exposed via the second passivation layer 6, and is electrically connected to the redistribution layer 5. The UBM layer 7 is an additional component improving the reliability of connection of the solder bump 9. That is, the UBM layer 7 provides a wetting layer to help the adhesion of the solder bump 9, and prevents permeation of the solder bump 9.

The UBM layer 7 may be formed by metallization using a well-known metal, and may have various configurations. For example, the UBM layer 7 may include Cu, Cu/Ni, Cu/Ni/Au, Cr/Cr-Cu/Cu, TiW/Cu, Al/NiV/Cu, or the like but is not limited thereto.

The solder bump 9 is formed on the UBM layer 7, and electrically connected to the UBM layer 7. In this case, the alloy layer 8 formed during a reflow process is provided between is the UBM layer 7 and the solder bump 9. For example, the solder bump 9 may include Sn, Sn/Ag, Sn/Bi, Sn/Cu, Sn/Au, Sn/Ag/Cu, SnNiAgCu, SnNiAg, or the like but is not limited thereto.

FIG. 4 illustrates one UBM layer 7, one alloy layer 8, and one solder bump 9, but the numbers thereof are not limited to 1 and a plurality of UBM layers 7, a plurality of alloy layers 8, and a plurality of solder bumps 9 may be provided.

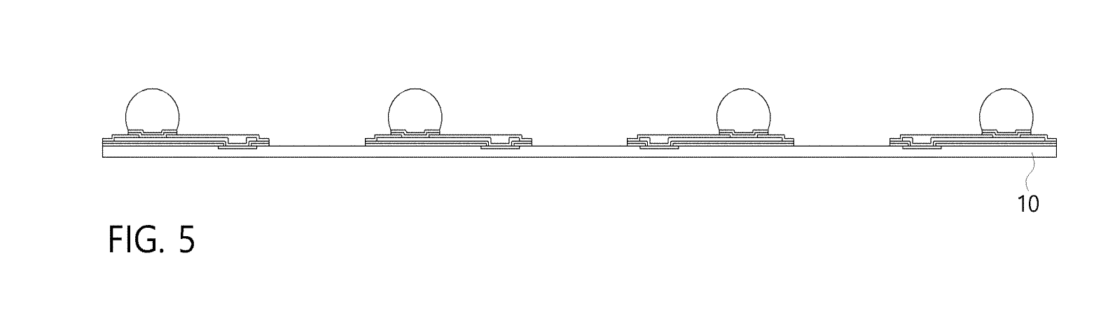

FIG. 5 is a side view of part of a wafer-level package including a redistribution structure according to an embodiment of the present disclosure.

As illustrated in FIG. 5, a wafer-level package including a redistribution structure according to an embodiment of the present disclosure is the same as the semiconductor device including the redistribution structure according to the previous embodiment of the present disclosure, except that the semiconductor chip 1 is replaced with a semiconductor wafer 10.

The semiconductor wafer 10 includes a plurality of uncut semiconductor chips 1. That is, the semiconductor wafer 10 may include chip regions occupied by the plurality of semiconductor chips 1, and cut regions of the chip regions. For example, the semiconductor wafer 10 may include a single crystal silicon wafer or a polycrystalline silicon wafer, but is not limited thereto.

The wafer-level package including the redistribution structure according to the present embodiment may further include a molding member to pack the other components thereof. The molding member is configured to mold the semiconductor chip 1 not to be exposed to the outside, and may include, for example, an epoxy mold compound (EMC) or the like but is not limited thereto.

An electrode pad 2, an insulating layer 3, a first passivation layer 4, a redistribution layer 5, a second passivation layer 6, a UBM layer 7, an alloy layer 8, and a solder bump 9 which are the other components, and the plurality of semiconductor chips 1 included in the semiconductor wafer 10 are as described above with reference to FIG. 4 and thus are not redundantly described here.

Next, two components (hereinafter referred to as a “first anti-warpage unit” and a “second anti-warpage unit”) configured to prevent a warpage caused when the redistribution layer 5 is formed to be thicker than that of the related art will be described below.

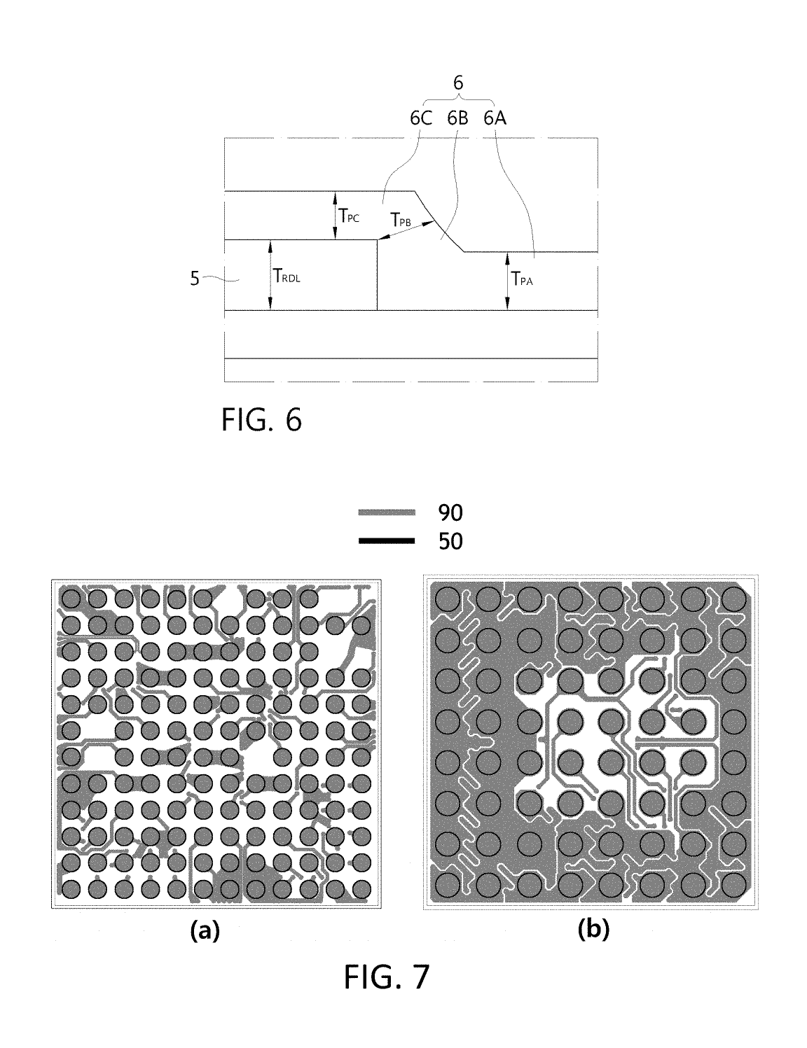

FIG. 6 is an enlarged view of a region of FIG. 4 indicated by a broken line.

Generally, the second passivation layer 6 having a thickness greater than or equal to that of the redistribution layer 5 is provided. That is, when the redistribution layer 5 is formed to be thicker than that of the related art, the second passivation layer 6 having the same thickness as the redistribution layer 5 is also formed to be thicker to correspond to the thickness of the redistribution layer 5. However, as the thickness of the second passivation layer 6 is increased, a physical stress applied to the semiconductor chips 1 and the semiconductor wafer 10 including the semiconductor chips 1 increases and thus a warpage occurs. Furthermore, as the thickness of the second passivation layer 6 is increased, the volume of the second passivation layer 6 is reduced more significantly during a heat treatment performed by a curing process, thereby triggering the warpage.

The first anti-warpage unit is configured to solve this problem. That is, the first anti-warpage unit includes the second passivation layer 6 having a thickness less than that of the redistribution layer 5.

Referring to FIG. 6, the second passivation layer 6 includes a side passivation layer 6A, an intermediate passivation layer 6B, and an upper passivation layer 6C. In this case, the side passivation layer 6A is a portion of the second passivation layer 6 spaced a certain distance from a side of the redistribution layer 5, and the upper passivation layer 6C is a portion of the second passivation layer 6 located on the redistribution layer 5. The intermediate passivation layer 6B is a region of the second passivation layer 6 between the side passivation layer 6A and the upper passivation layer 6C.

That is, the first anti-warpage unit includes the side passivation layer 6A having a thickness T_{PA}, the intermediate passivation layer 6B having a thickness T_{PB}, and the upper passivation layer 6C having a thickness T_{PC} which are less than a thickness T_{RDL} of the redistribution layer 5 (here, T_{RDL}>T_{PA}, T_{RDL}>T_{PB}, T_{RDL}>T_{PC}). In this case, even when the same process is performed to form the second passivation layer 6, the side passivation layer 6A, the intermediate passivation layer 6B, and the upper passivation layer 6C may have different thicknesses (T_{PA}≠T_{PB}T_{PC}) and the thickness T_{PA} of the side passivation layer 6A may be greater than the thickness T_{PC} of the upper passivation layer 6C as illustrated in FIG. 5. This phenomenon may occur due to positional characteristics of the side passivation layer 6A, the intermediate passivation layer 6B, and the upper passivation layer 6C or characteristics of materials of components which are in direct contact with the side passivation layer 6A, the intermediate passivation layer 6B, and the upper passivation layer 6C (hereinafter referred to as “passivation layer formation environmental characteristics”).

Especially, for normal operation of the second passivation layer 6, the thickness T_{PB} of the intermediate passivation layer 6B, i.e., the distance between an upper corner of the redistribution layer 5 and an upper portion of the second passivation layer 6 spaced a minimum distance from the upper corner of the redistribution layer 5, (hereinafter referred to as a “first limit range”) should be 5 μm or more. That is, when the thickness T_{PB} of the intermediate passivation layer 6B is less than 5 μm, the redistribution layer 5 may be physically or chemically damaged and thus be easily exposed to the outside.

In contrast, the thickness T_{PB} of the intermediate passivation layer 6B is determined by the thickness T_{PA} of the side passivation layer 6A and the thickness T_{PC} of the upper passivation layer 6C. Thus, it is preferable that the thickness T_{PA} of the side passivation layer 6A be greater than or equal to 60% of the thickness T_{RDL} of the redistribution layer 5 and less than 100% of the thickness T_{RDL} of the redistribution layer 5, and the thickness T_{PC} of the upper passivation layer 6C be greater than or equal to 40% of the thickness T_{RDL} of the redistribution layer 5 and less than 75% of the thickness T_{RDL} of the redistribution layer 5 (hereinafter referred to as a “second limit range”) so as to satisfy the “first limit range” while taking into consideration the “passivation layer formation environmental characteristics.” In this case, the thickness T_{PB} of the intermediate passivation layer 6B is less than 5 μm when the thickness T_{PA} of the side passivation layer 6A is less than 60% of the thickness T_{RDL} of the redistribution layer 5 or when the thickness T_{PC} of the upper passivation layer 6C is less than 40% of the thickness T_{RDL} of the redistribution layer 5.

For example, when the thickness T_{RDL} of the redistribution layer 5 is greater than or equal to 20 μm and less than or equal to 30 μm, the thickness T_{PA} of the side passivation layer 6A is greater than or equal to 12 μm and less than 30 μm and the thickness T_{PC} of the upper passivation layer 6C is greater than or equal to 8 μm and less than 22.5 μm.

A cross-sectional area A_{SW} of the semiconductor wafer 10, a total cross-sectional area A_{SC} of the semiconductor chip 1, a cross-sectional area A_{RDL} of the redistribution layer 5, etc. were measured on a plane of a wafer-level package with a redistribution layer 5 having a thickness of 10 μm according to the related art and a plane of a wafer-level package with a redistribution layer 5 having a thickness of 20 μm or more (manufactured according to the present disclosure).

FIG. 7 illustrates examples of a region of the redistribution layer 5 on a plane of a wafer-level package according to a thickness of the redistribution layer 5. FIG. 7 (a) illustrates a region of the redistribution layer 5 on the plane of the wafer-level package when the redistribution layer 5 has a thickness of 10 μm. FIG. 7 (b) illustrates a region of the redistribution layer 5 on the plane of the wafer-level package when the redistribution layer 5 has a thickness of 20 μm or more. Here, regions marked in blue represent regions of the redistribution layer 5, and regions marked in pink represent regions of the solder bump 9. A result of measurement is as shown in Table 1 below.

TABLE 1

| | Wafer-level | Wafer-level |
|---|---|---|
| | package with | package with |
| | redistribution | redistribution |
| | layer having a | layer having a |
| | thickness of | thickness of 20 |
| | 10 μm | μm or more |
| Ratio of cross-sectional area of | 30% to 50% | 50% to 75% |
| redistribution layer to that of | | |
| semiconductor wafer | | |
| ([A_{RDL}]/[A_{SW}] %) | | |
| Ratio of cross-sectional area of | 25% to 45% | 45% to 70% |
| redistribution layer to that of | | |
| semiconductor chip | | |
| ([A_{RDL}]/[A_{SC}] %) | | |

Referring to Table 1, as the thickness of the redistribution layer 5 was increased, the cross-sectional area of the redistribution layer 5 increased and thus a ratio of the cross-sectional area of the redistribution layer 5 to that of the semiconductor wafer 10 (hereinafter referred to as a “first cross-sectional area ratio”) and a ratio of the cross-sectional area of the redistribution layer 5 to that of the semiconductor chip 1 (hereinafter referred to as a “second cross-sectional area ratio”) also increased. That is, referring to FIG. 7 (a), when the thickness of the redistribution layer 5 was 10 μm, the “first cross-sectional area ratio” and the “second cross-sectional area ratio” on the plane were respectively in a range of about 30% to 50% and a range of about 25% to 45%. Referring to FIG. 7 (b), when the thickness of the redistribution layer 5 was 20 μm or more, the “first cross-sectional area ratio” was in a range of about 50% to 75% and the “second cross-sectional area ratio” was in a range of about 45% to 70%.

However, the “first cross-sectional area ratio” and the “second cross-sectional area ratio” may vary according to a process method. In this case, as these cross-sectional area ratios become increased, the thicknesses T_{PA}, T_{PB}, and T_{PC} of the second passivation layer 6 should be increased. This is because the first limit range should be increased when the ratio of the redistribution layer 5 is increased. In this case, the thicknesses T_{PA}, T_{PB}, and T_{PC} of the second passivation layer 6 should be adjusted to be within the “first limit range.” In other words, the thicknesses thickness T_{PA}, T_{PB}, and T_{PC} of the second passivation layer 6 may be changed according to the “first cross-sectional area ratio” and the “second cross-sectional area ratio,” and may be increased to be within the “first limit range” when these cross-sectional area ratios are increased.

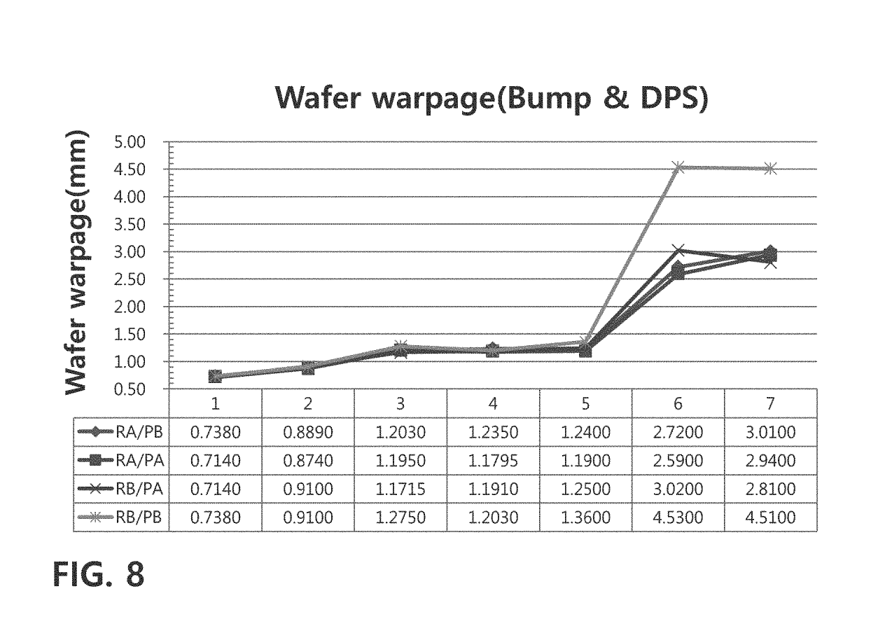

FIG. 8 is a graph showing a degree of a warpage occurred during a semiconductor device manufacturing process according to materials of the redistribution layer 5 and the second passivation layer 6. A degree of a warpage occurred during each of operations of the semiconductor device manufacturing process was measured while performing the semiconductor device manufacturing process, when the thickness of the redistribution layer 5 was the same but materials of the redistribution layer 5 and the second passivation layer 6 were different. A result of measurement is illustrated in FIG. 8. In FIG. 8, ‘RA’ and ‘RB’ represent materials of the redistribution layer 5, and ‘PA’ and TB′ represent materials of the second passivation layer 6. In this case, the materials RA and RB are different in terms of the content of a copper base and the types of additives. That is, the material RB includes all of a brightener, a suppressor, and a leveler as additives, and the material ‘RA’ includes the brightener and the suppressor as additives but excludes the leveler. The content of copper in the material RA is less than that of copper in the material RB.

In FIG. 8, ‘1’ represents data measured after a process of forming the first passivation layer 4, ‘2’ represents data measured after a process of forming the redistribution layer 5, ‘3’ represents data measured after a process of forming the second passivation layer 6, and ‘4’ represents data measured after a process of forming the solder bump 9. ‘DPS’ is an abbreviation for a die process service whereby a wafer-level chip-scale package (WLCSP) is delivered to a client after being divided and packed in units of chips. That is, ‘5’ represents data measured through the DPS, ‘6’ represents data measured after back grinding (wafer grinding), and ‘7’ represents data measured after a lamination tape (LT) was detached.

Referring to FIG. 8, a degree of warpage occurring during the semiconductor device manufacturing process varied according to the materials of the redistribution layer 5 and the second passivation layer 6. Particularly, it was found that selection of the material of the redistribution layer 5 is a more important factor in preventing the occurrence of the warpage. That is, it was found that the material RA including the brightener and the suppressor as additives, excluding the leveler, less warped than the material RB having a higher copper content and including all the brightener, the suppressor and the leveler as additives. As described above, the material RA less warped than the material RB, since the number of additives therein was less than that of additives in the material RB and thus generation of a eutectoid due to hydrogen and organic impurities generated during the formation of the redistribution layer 5 may be minimized, thereby reducing residual stress.

Accordingly, the second anti-warpage unit is obtained when the redistribution layer 5 is formed using such material characteristics. That is, the second anti-warpage unit is obtained when the redistribution layer 5 includes copper and additives. The additives include the brightener and the suppressor excluding the leveler. Furthermore, the second anti-warpage unit includes copper and additives in appropriate content ranges.

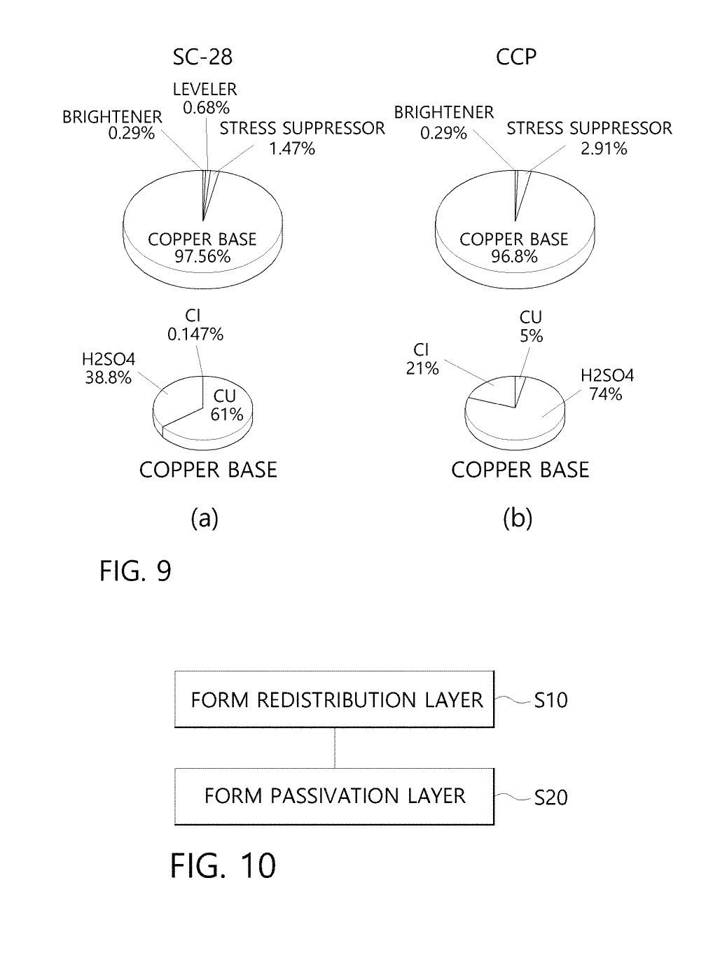

FIG. 9 illustrates composition ratios of (a) the material of the redistribution layer 5 warped to a highest degree and (b) the material of the redistribution layer 5 warped to a lowest degree among the materials of the redistribution layer 5 of FIG. 8.

Referring to FIG. 9 (a), in the material RB of the redistribution layer 5 warped to the highest degree, the content of the copper base is 97.56 wt %, and the contents of the brightener, the suppressor, and the leveler serving as additives are respectively 0.29 wt %, 1.47 wt %, and 0.68 wt %. In this case, in the copper base of the material RB, the content of Cu is about 61 wt % (about 59.5 wt %, based on the total weight of the copper base), the content of H₂SO₄ is about 38.8 wt % (about 37.9 wt %, based on the total weight of the copper base), and the content of Cl is about 0.2 wt % (about 0.14 wt %, based on the total weight of the copper base).

Referring to FIG. 9 (b), in the material RA of the redistribution layer 5 warped to the lowest degree, the content of the copper base is 96.8 wt %, the contents of the brightener and the suppressor serving as additives are respectively 0.29 wt % and 2.91 wt %, and the leveler is excluded. In this case, in the copper base of the material RA, the content of Cu is about 5 wt % (about 4.8 wt %, based on the total weight of the copper base), the content of H₂SO₄ is about 74 wt % (about 71.6 wt %, based on the total weight of the copper base), and the content of Cl is about 21 wt % (about 20.3 wt %, based on the total weight of the copper base).

That is, when FIGS. 9 (a) and (b) are compared with each other, the content of Cu contained in the copper base may be a certain wt % or less, preferably, 10 wt % or less, and more preferably, 5 wt % or less so that the redistribution layer 5 may warp to a lowest degree. When the content of Cu contained in the copper base exceeds the above range, the redistribution layer 5 may excessively warp as illustrated in FIG. 9 (a). Furthermore, the content of the suppressor may be in a certain range of wt %, preferably, a range of 2 to 4 wt %, and more preferably, a range of 2 to 3 wt %, based on the total weight of the copper base. The redistribution layer 5 may excessively warp as illustrated in FIG. 9 (a) when the content of the suppressor is below the above range, and the physical properties, e.g., strength, electrical conductivity, etc., of the redistribution layer 5 may not be appropriate when the content of the suppressor is beyond the above range.

A method of manufacturing a semiconductor device having a redistribution structure according to an embodiment of the present disclosure will be described below.

FIG. 10 illustrates a method of manufacturing a semiconductor device having a redistribution structure according to an embodiment of the present disclosure.

The method of manufacturing a semiconductor device having a redistribution structure according to an embodiment of the present disclosure includes operations S10 and S20 as illustrated in FIG. 10.

In operation S10, a redistribution layer is formed. The redistribution layer 5 is formed on the semiconductor wafer 10. Prior to operation S10, a structure may be prepared by sequentially providing the semiconductor wafer 10, the electrode pad 2, the insulating layer 3, and the first passivation layer 4. In operation S10, the redistribution layer 5 may be formed on the structure. In this case, the redistribution layer 5 may include the above-described second anti-warpage unit.

In operation S20, a passivation layer is formed. The second passivation layer 6 having a thickness less than that of the redistribution layer 5 is formed to cover the redistribution layer 5 while partially exposing the redistribution layer 5. In this case, the second passivation layer 6 may include the above-described first anti-warpage unit.

Operation S20 may further include heat-treating the second passivation layer 6 by a curing process after the formation of the second passivation layer 6. For example, the second passivation layer 6 may be heat-treated at 200° C. to 375° C. but is not limited thereto.

In a semiconductor device and a wafer-level package each including a redistribution structure configured as described above and a method of manufacturing the semiconductor device according to an embodiment of the present disclosure, a redistribution layer which is thicker than that of the related art is provided to improve the electrode efficiencies of the semiconductor device and the wafer-level package and an anti-warpage unit is provided to prevent a warpage due to the redistribution layer which is thicker than that of the related art.

While exemplary embodiments of the present disclosure have been described above, various changes may be made therein without departing from the scope of the invention. The scope of the present disclosure is not limited to these embodiments and should be determined by the scope of the following claims and equivalents thereto.

What is claimed is:

1. A semiconductor device comprising:
a semiconductor chip;
a redistribution layer provided on the semiconductor chip; and
a passivation layer covering the redistribution layer while partially exposing the redistribution layer,
wherein the passivation layer has a thickness less than that of the redistribution layer.

2. The semiconductor device of claim 1, wherein the redistribution layer has a thickness greater than or equal to 20 μm and less than or equal to 30 μm.

3. The semiconductor device of claim 2, wherein a distance between an upper corner of the redistribution layer and an upper portion of the passivation layer spaced a minimum distance from the upper corner is 5 μm or more.

4. The semiconductor device of claim 2, wherein a thickness of a side passivation layer is greater than that of an upper passivation layer, the side passivation layer being a region of the passivation layer spaced a certain distance from a side of the redistribution layer, and the upper passivation layer being a region of the passivation layer located on the redistribution layer.

5. The semiconductor device of claim 4, wherein the thickness of the side passivation layer is greater than or equal to 60% and less than 100% of that of the redistribution layer, and
the thickness of the upper passivation layer is greater than or equal to 40% and less than 75% of that of the redistribution layer.

6. The semiconductor device of claim 5, wherein, as a ratio of a cross-sectional area ratio of the redistribution layer to that of the semiconductor chip is increased, the thickness of the passivation layer is increased.

7. The semiconductor device of claim 1, wherein the redistribution layer comprises copper and additives,
wherein the additives comprise a brightener and a suppressor excluding a leveler.

8. A semiconductor device comprising:
a semiconductor chip;
a redistribution layer provided on the semiconductor chip, and including copper and additives; and
a passivation layer covering the redistribution layer while partially exposing the redistribution layer,
wherein the additives comprise a brightener and a suppressor excluding a leveler.

9. The semiconductor device of claim 8, wherein a content of the copper included in the redistribution layer is 10 wt % or less.

10. The semiconductor device of claim 8, wherein a content of the suppressor included in the redistribution layer is 2 wt % or more and 4 wt % or less.

11. A wafer-level package comprising:
a semiconductor wafer;
a redistribution layer provided on the semiconductor wafer; and
a passivation layer covering the redistribution layer while partially exposing the redistribution layer,
wherein the passivation layer has a thickness less than that of the redistribution layer.

12. A method of manufacturing a semiconductor device having a redistribution structure, the method comprising:
(a) forming a redistribution layer on a semiconductor wafer; and
(b) forming a passivation layer to cover the redistribution layer while partially exposing the redistribution layer, the passivation layer having a thickness less than that of the redistribution layer.
